(19) United States
(12) Patent Application Publication
(10) Pub. No.: US 2024/0178008 A1
(43) Pub. Date: May 30, 2024

(54) COATING METHOD, PROCESSING APPARATUS, NON-TRANSITORY COMPUTER-READABLE RECORDING MEDIUM, SUBSTRATE PROCESSING METHOD AND METHOD OF MANUFACTURING SEMICONDUCTOR DEVICE

(71) Applicant: Kokusai Electric Corporation, Tokyo (JP)

(72) Inventor: Arito OGAWA, Toyama-shi (JP)

(73) Assignee: Kokusai Electric Corporation, Tokyo (JP)

(21) Appl. No.: 18/430,036

(22) Filed: Feb. 1, 2024

Related U.S. Application Data
(63) Continuation of application No. PCT/JP21/34376, filed on Sep. 17, 2021.

(51) Int. Cl. H01L 21/67; H01L 21/02

(52) U.S. Cl. CPC H01L 21/67017; H01L 21/02271; H01L 21/67098; H01L 21/6719

(57) ABSTRACT

There is provided a technique that includes: (a) supplying a first process gas to a process vessel; (b) supplying a second process gas different from the first process gas to the process vessel; (c) supplying a third process gas different from each of the first process gas and the second process gas to the process vessel; (d) performing a first cycle X times, the first cycle including performing (a) and (b); (e) performing a second cycle Y times, the second cycle including performing (d) and (c); and (f) changing X in a next execution of the second cycle according to the number of previous executions of the second cycle in (e).

### CROSS-REFERENCE TO RELATED PATENT APPLICATION

This application is a bypass continuation application of PCT International Application No. PCT/JP2021/034376, filed on Sep. 17, 2021, in the WIPO, the entire contents of which are hereby incorporated by reference.

### BACKGROUND

### 1. Field

The present disclosure relates to a coating method, a processing apparatus, a non-transitory computer-readable recording medium, a substrate processing method and a method of manufacturing a semiconductor device.

### 2. Related Art

According to some related arts, as a part of a manufacturing process of a semiconductor device, a step of forming a film on a substrate in a process vessel of a substrate processing apparatus may be performed.

However, when the film is formed on the substrate, the film may also be formed on an inner wall of the process vessel. As an accumulative thickness of the film increases, the film may peel off and particles may be generated.

### SUMMARY

According to the present disclosure, there is provided a technique capable of suppressing a generation of particles.

According to one embodiment of the present disclosure, there is provided a technique that includes: (a) supplying a first process gas to a process vessel; (b) supplying a second process gas different from the first process gas to the process vessel; (c) supplying a third process gas different from each of the first process gas and the second process gas to the process vessel; (d) performing a first cycle X times, the first cycle comprising performing (a) and (b); (e) performing a second cycle Y times, the second cycle comprising performing (d) and (c); and (f) changing X in a next execution of the second cycle according to the number of previous executions of the second cycle in (e).

### BRIEF DESCRIPTION OF THE DRAWINGS

FIG. 1 is a diagram schematically illustrating a vertical cross-section of a vertical type process furnace of a substrate processing apparatus according to one or more embodiments of the technique of the present disclosure.

FIG. 2 is a diagram schematically illustrating a horizontal cross-section taken along a line A-A (shown in FIG. 1) of the vertical type process furnace of the substrate processing apparatus according to the embodiments of the technique of the present disclosure.

FIG. 3 is a block diagram schematically illustrating a configuration of a controller and related components of the substrate processing apparatus according to the embodiments of the technique of the present disclosure.

FIG. 4 is a diagram schematically illustrating a process flow according to the embodiments of the technique of the present disclosure.

FIG. 5 is a diagram schematically illustrating an example of a gas supply in a film forming step according to the embodiments of the technique of the present disclosure.

FIG. 6 is a diagram schematically illustrating an example of a gas supply in a pre-coating step according to the embodiments of the technique of the present disclosure.

FIGS. 7A and 7B are diagrams schematically illustrating states of a film formed on a surface of a component such as an inner wall of a process vessel in a case where the pre-coating step shown in FIG. 6 is performed, respectively, and FIGS. 7C and 7D are diagrams schematically illustrating states of the film formed on the surface of the component such as the inner wall of the process vessel in a case where the pre-coating step is not performed, respectively.

FIG. 8 is a diagram schematically illustrating a modified example of the gas supply in the pre-coating step according to the embodiments of the technique of the present disclosure.

FIG. 9 is a diagram schematically illustrating another modified example of the gas supply in the pre-coating step according to the embodiments of the technique of the present disclosure.

FIG. 10 is a diagram schematically illustrating a modified example of the gas supply in the film forming step according to the embodiments of the technique of the present disclosure.

### DETAILED DESCRIPTION

### Embodiments of Present Disclosure

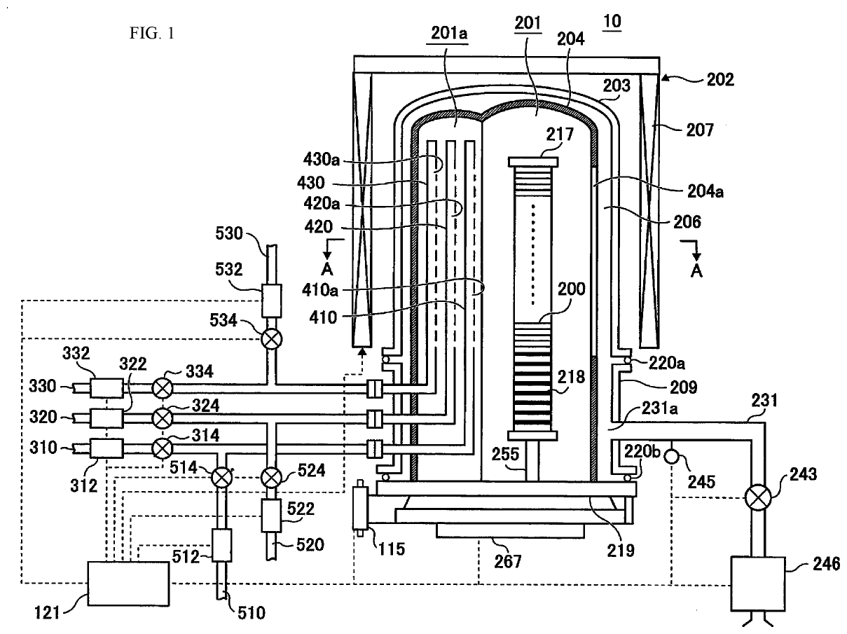

Hereinafter, one or more embodiments (also simply referred to as “embodiments”) according to the technique of the present disclosure will be described with reference to FIGS. 1 to 7. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

A substrate processing apparatus 10 according to the present embodiments includes a process furnace 202 provided with a heater 207 serving as a heating structure (which is a heating device or a heating system). The heater 207 is of a cylindrical shape, and is vertically installed while being supported by a heater base (not shown) serving as a support plate.

An outer tube 203 constituting a reaction tube (which is a reaction vessel or a process vessel) is provided in an inner side of the heater 207 to be aligned in a manner concentric with the heater 207. For example, the outer tube 203 is made of a heat resistant material such as quartz (SiO₂) and silicon carbide (SiC). The outer tube 203 is of a cylindrical shape with a closed upper end and an open lower end. A manifold (which is an inlet flange) 209 is provided under the outer tube 203 to be aligned in a manner concentric with the outer tube 203. For example, the manifold 209 is made of a metal such as stainless steel (SUS). The manifold 209 is of a cylindrical shape with open upper and lower ends. An O-ring 220a serving as a seal is provided between the upper end of the manifold 209 and the outer tube 203. As the manifold 209 is supported by the heater base (not shown), the outer tube 203 is installed vertically.

An inner tube 204 constituting the reaction vessel is provided in an inner side of the outer tube 203. For example, the inner tube 204 is made of a heat resistant material such as quartz (SiO₂) and silicon carbide (SiC). The inner tube 204 is of a cylindrical shape with a closed upper end and an open lower end. The process vessel (reaction vessel) is constituted mainly by the outer tube 203, the inner tube 204 and the manifold 209. At least a portion of the inner wall of the processing vessel is constituted by quartz. A process chamber 201 is provided in a hollow cylindrical portion of the process vessel (that is, an inside of the inner tube 204).

The process chamber 201 is configured to be capable of accommodating a plurality of wafers including a wafer 200 serving as a substrate in a horizontal orientation to be vertically arranged in a multistage manner by a boat 217 serving as a substrate support. Hereinafter, the plurality of wafers including the wafer 200 may also be simply referred to as wafers 200.

Nozzles 410, 420 and 430 are installed in the process chamber 201 so as to penetrate a side wall of the manifold 209 and the inner tube 204. Gas supply pipe 310, 320 and 330 are connected to the nozzles 410, 420 and 430, respectively. However, the process furnace 202 of the present embodiments is not limited to the example described above.

Mass flow controllers (MFCs) 312, 322 and 332 serving as flow rate controllers (flow rate control structures) and valves 314, 324 and 334 serving as opening/closing valves are sequentially installed at the gas supply pipes 310, 320 and 330 in this order from upstream sides to downstream sides of the gas supply pipes 310, 320 and 330, respectively. Gas supply pipes 510, 520 and 530 through which an inert gas is supplied are connected to the gas supply pipes 310, 320 and 330 at downstream sides of the valves 314, 324 and 334, respectively. MFCs 512, 522 and 532 serving as flow rate controllers (flow rate control structures) and valves 514, 524 and 534 serving as opening/closing valves are sequentially installed at the gas supply pipes 510, 520 and 530 in this order from upstream sides to downstream sides of the gas supply pipes 510, 520 and 530, respectively.

The nozzles 410, 420 and 430 are connected to front ends (tips) of the gas supply pipes 310, 320 and 330, respectively. Each of the nozzles 410, 420 and 430 may include an L-shaped nozzle. Horizontal portions of the nozzles 410, 420 and 430 are installed so as to penetrate the side wall of the manifold 209 and the inner tube 204. Vertical portions of the nozzles 410, 420 and 430 are installed in a preliminary chamber 201a of a channel shape (a groove shape) protruding outward in a radial direction of the inner tube 204 and extending in the vertical direction. That is, the vertical portions of the nozzles 410, 420 and 430 are installed in the preliminary chamber 201a toward the upper end of the inner tube 204 (in a direction in which the wafers 200 are arranged) and along an inner wall of the inner tube 204.

The nozzles 410, 420 and 430 extend from a lower region of the process chamber 201 to an upper region of the process chamber 201. The nozzles 410, 420 and 430 are provided with a plurality of gas supply holes 410a, a plurality of gas supply holes 420a and a plurality of gas supply holes 430a facing the wafers 200, respectively. Thereby, a gas such as a process gas can be supplied to the wafers 200 through the gas supply holes 410a of the nozzle 410, the gas supply holes 420a of the nozzle 420 and the gas supply holes 430a of the nozzle 430. The gas supply holes 410a, the gas supply holes 420a and the gas supply holes 430a are provided from a lower portion to an upper portion of the inner tube 204. An opening area of each of the gas supply holes 410a, the gas supply holes 420a and the gas supply holes 430a is the same, and each of the gas supply holes 410a, the gas supply holes 420a and the gas supply holes 430a is provided at the same pitch. However, the gas supply holes 410a, the gas supply holes 420a and the gas supply holes 430a are not limited thereto. For example, the opening area of each of the gas supply holes 410a, the gas supply holes 420a and the gas supply holes 430a may gradually increase from the lower portion to the upper portion of the inner tube 204 to further uniformize a flow rate of the gas supplied through the gas supply holes 410a, the gas supply holes 420a and the gas supply holes 430a.

The gas supply holes 410a of the nozzle 410, the gas supply holes 420a of the nozzle 420 and the gas supply holes 430a of the nozzle 430 are provided from a lower portion to an upper portion of the boat 217 described later. Therefore, the process gas supplied into the process chamber 201 through the gas supply holes 410a, the gas supply holes 420a and the gas supply holes 430a is supplied onto the wafers 200 accommodated in the boat 217 from the lower portion to the upper portion thereof, that is, the entirety of the wafers 200 accommodated in the boat 217. It is preferable that the nozzles 410, 420 and 430 extend from the lower region to the upper region of the process chamber 201. However, the nozzles 410, 420 and 430 may extend only to the vicinity of a ceiling of the boat 217.

A first process gas (which is a gas containing a first metal element and serving as one of process gases) is supplied into the process chamber 201 through the gas supply pipe 310 provided with the MFC 312 and the valve 314 and the nozzle 410.

A second process gas (which is a gas different from the first process gas, containing a Group 15 element serving as a second element, and serving as one of the process gases) is supplied into the process chamber 201 through the gas supply pipe 320 provided with the MFC 322 and the valve 324 and the nozzle 420.

A third process gas (which is a gas different from the first process gas and different from the second process gas, containing a Group 14 element serving as a third element, and serving as one of the process gases) is supplied into the process chamber 201 through the gas supply pipe 330 provided with the MFC 332 and the valve 334 and the nozzle 430.

The inert gas such as nitrogen (N₂) gas is supplied into the process chamber 201 through the gas supply pipes 510, 520 and 530 provided with the MFCs 512, 522 and 532 and the valves 514, 524 and 534, respectively, and the nozzles 410, 420 and 430. While the present embodiments will be described by way of an example in which the N₂ gas is used as the inert gas, the inert gas according to the present embodiments is not limited thereto. For example, instead of the N₂ gas, a rare gas such as argon (Ar) gas, helium (He) gas, neon (Ne) gas and xenon (Xe) gas may be used as the inert gas.

When the first process gas is supplied through the gas supply pipe 310, a first process gas supplier (which is a first process gas supply structure or a first process gas supply system) is constituted mainly by the gas supply pipe 310, the MFC 312 and the valve 314. The first process gas supplier may further include the nozzle 410. Further, when the second process gas is supplied through the gas supply pipe 320, a second process gas supplier (which is a second process gas supply structure or a second process gas supply system) is constituted mainly by the gas supply pipe 320, the MFC 322 and the valve 324. The second process gas supplier may further include the nozzle 420. Further, when the third process gas is supplied through the gas supply pipe 330, a third process gas supplier (which is a third process gas supply structure or a third process gas supply system) is constituted mainly by the gas supply pipe 330, the MFC 332 and the valve 334. The third process gas supplier may further include the nozzle 430. A process gas supplier (which is a process gas supply structure or a process gas supply system) is constituted by the first process gas supplier, the second process gas supplier and the third process gas supplier. Further, the process gas supplier may further include the nozzles 410, 420 and 430. In addition, an inert gas supplier (which is an inert gas supply structure or an inert gas supply system) is constituted mainly by the gas supply pipes 510, 520 and 530, the MFCs 512, 522 and 532 and the valves 514, 524 and 534.

According to the present embodiments, the gas is supplied into a vertically long annular space provided in the preliminary chamber 201a which is defined by the inner wall of the inner tube 204 and edges (peripheries) of the wafers 200 through the nozzles 410, 420 and 430. The gas is ejected into the inner tube 204 through the gas supply holes 410a of the nozzle 410, the gas supply holes 420a of the nozzle 420 and the gas supply holes 430a of the nozzle 430 facing the wafers 200. Specifically, gases such as the first process gas, the second process gas and the third process gas are ejected into the inner tube 204 in a direction parallel to surfaces of the wafers 200 through the gas supply holes 410a of the nozzle 410, the gas supply holes 420a of the nozzle 420 and the gas supply holes 430a of the nozzle 430, respectively.

An exhaust hole (which is an exhaust port) 204a is a through-hole facing the nozzles 410, 420 and 430, and is provided at a side wall of the inner tube 204. For example, the exhaust hole 204a may be of a narrow slit-shaped through-hole elongating vertically. The gas supplied into the process chamber 201 through the gas supply holes 410a of the nozzle 410, the gas supply holes 420a of the nozzle 420 and the gas supply holes 430a of the nozzle 430 flows over the surfaces of the wafers 200. The gas that has flowed over the surfaces of the wafers 200 is exhausted through the exhaust hole 204a into a gap (that is, an exhaust path 206) provided between the inner tube 204 and the outer tube 203. The gas flowing in the exhaust path 206 flows into an exhaust pipe 231 and is then discharged (exhausted) out of the process furnace 202.

The exhaust hole 204a is provided to face the wafers 200. The gas supplied in the vicinity of the wafers 200 in the process chamber 201 through the gas supply holes 410a, the gas supply holes 420a and the gas supply holes 430a flows in the horizontal direction. The gas that has flowed in the horizontal direction is exhausted through the exhaust hole 204a into the exhaust path 206. The exhaust hole 204a is not limited to the slit-shaped through-hole. For example, the exhaust hole 204a may be configured as a plurality of holes.

The exhaust pipe 231 through which an inner atmosphere of the process chamber 201 is exhausted is installed at the manifold 209. A pressure sensor 245 serving as a pressure detector (pressure detecting structure) configured to detect an inner pressure of the process chamber 201, an APC (Automatic Pressure Controller) valve 243 and a vacuum pump 246 serving as a vacuum exhaust apparatus are sequentially installed at the exhaust pipe 231 in this order from an upstream side to a downstream side of the exhaust pipe 231. With the vacuum pump 246 in operation, the APC valve 243 may be opened or closed to perform a vacuum exhaust of the process chamber 201 or stop the vacuum exhaust. Further, with the vacuum pump 246 in operation, an opening degree of the APC valve 243 may be adjusted in order to adjust the inner pressure of the process chamber 201. An exhauster (which is an exhaust structure or an exhaust system) is constituted mainly by the exhaust hole 204a, the exhaust path 206, the exhaust pipe 231, the APC valve 243 and the pressure sensor 245. The exhauster may further include the vacuum pump 246.

A seal cap 219 serving as a furnace opening lid capable of airtightly sealing a lower end opening of the manifold 209 is provided under the manifold 209. The seal cap 219 is in contact with the lower end of the manifold 209 from thereunder. For example, the seal cap 219 is made of a metal such as SUS, and is of a disk shape. An O-ring 220b serving as a seal is provided on an upper surface of the seal cap 219 so as to be in contact with the lower end of the manifold 209. A rotator 267 configured to rotate the boat 217 accommodating the wafers 200 is provided at the seal cap 219 in a manner opposite to the process chamber 201. A rotating shaft 255 of the rotator 267 is connected to the boat 217 through the seal cap 219. As the rotator 267 rotates the boat 217, the wafers 200 are rotated. The seal cap 219 may be elevated or lowered in the vertical direction by a boat elevator 115 serving as an elevating structure vertically provided outside the outer tube 203. When the seal cap 219 is elevated or lowered in the vertical direction by the boat elevator 115, the boat 217 may be transferred (loaded) into the process chamber 201 or transferred (unloaded) out of the process chamber 201. The boat elevator 115 serves as a transfer device (which is a transfer structure or a transfer system) that loads the boat 217 and the wafers 200 accommodated in the boat 217 into the process chamber 201 or unloads the boat 217 and the wafers 200 accommodated in the boat 217 out of the process chamber 201.

The boat 217 is configured to accommodate (or support) the wafers 200 (for example, 25 to 200 wafers) while the wafers 200 are horizontally oriented with their centers aligned with one another with a predetermined interval therebetween in a vertical direction. For example, the boat 217 is made of a heat resistant material such as quartz and SiC. A plurality of dummy substrates 218 horizontally oriented are provided under the boat 217 in a multistage manner. Each of the dummy substrates 218 is made of a heat resistant material such as quartz and SiC. With such a configuration, the dummy substrates 218 suppress the transmission of the heat from the heater 207 to the seal cap 219. However, the present embodiments are not limited thereto. For example, instead of the dummy substrates 218, a heat insulating cylinder (not shown) such as a cylinder made of a heat resistant material such as quartz and SiC may be provided under the boat 217.

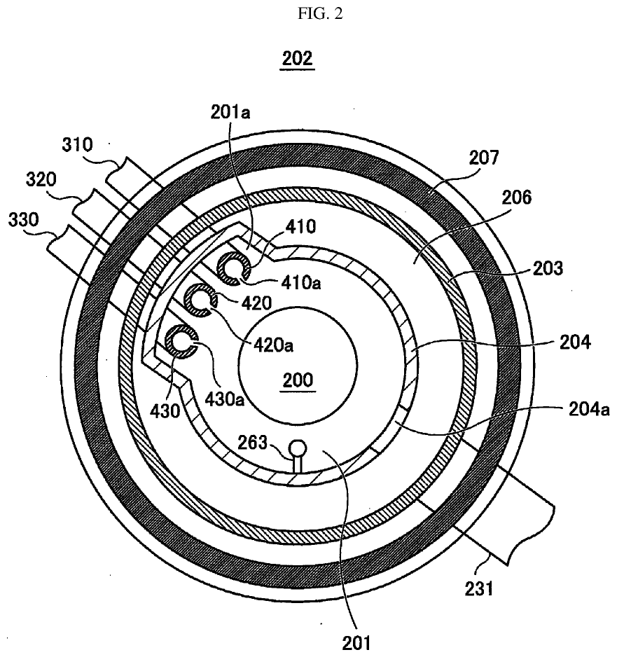

As shown in FIG. 2, a temperature sensor 263 serving as a temperature detector is installed in the inner tube 204. An amount of the current supplied (or applied) to the heater 207 is adjusted based on temperature information detected by the temperature sensor 263 such that a desired temperature distribution of an inner temperature of the process chamber 201 can be obtained. Similar to the nozzles 410, 420 and 430, the temperature sensor 263 is L-shaped, and is provided along the inner wall of the inner tube 204.

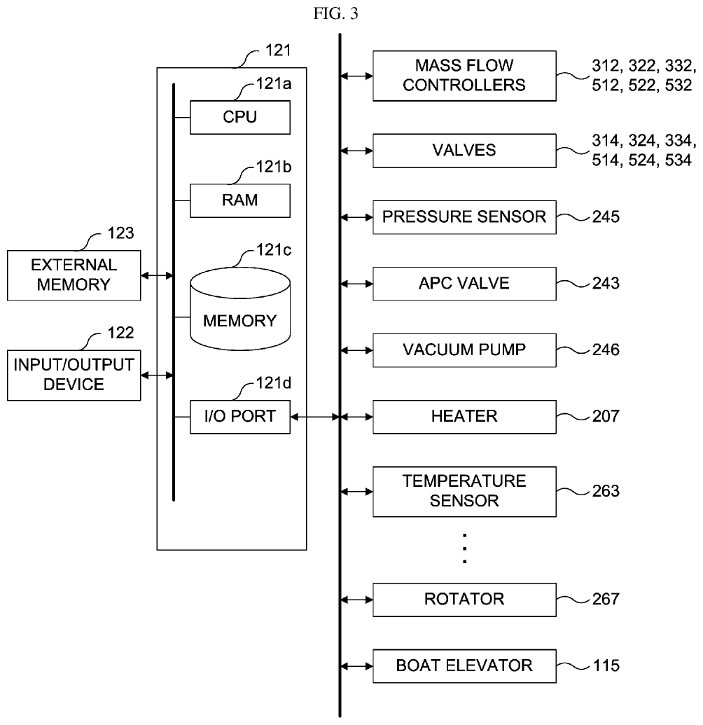

As shown in FIG. 3, a controller 121 serving as a control device (or a control structure) is constituted by a computer including a CPU (Central Processing Unit) 121a, a RAM (Random Access Memory) 121b, a memory 121c and an I/O port 121d. The RAM 121b, the memory 121c and the I/O port 121d may exchange data with the CPU 121a through an internal bus (not shown). For example, an input/output device 122 constituted by a component such as a touch panel is connected to the controller 121.

The memory 121c is configured by a component such as a flash memory and a hard disk drive (HDD). For example, a control program configured to control an operation of the substrate processing apparatus 10 or a process recipe containing information on sequences and conditions of a method of manufacturing a semiconductor device described later is readably stored in the memory 121c. The process recipe is obtained by combining steps of the method of manufacturing the semiconductor device described later such that the controller 121 can execute the steps to acquire a predetermined result, and functions as a program. Hereafter, the process recipe and the control program may be collectively or individually referred to as a “program”. In the present specification, the term “program” may refer to the process recipe alone, may refer to the control program alone, or may refer to a combination of the process recipe and the control program. The RAM 121b functions as a memory area (work area) where a program or data read by the CPU 121a is temporarily stored.

The I/O port 121d is connected to the components described above such as the MFCs 312, 322, 332, 512, 522 and 532, the valves 314, 324, 334, 514, 524 and 534, the pressure sensor 245, the APC valve 243, the vacuum pump 246, the heater 207, the temperature sensor 263, the rotator 267 and the boat elevator 115.

The CPU 121a is configured to read the control program from the memory 121c and execute the read control program. In addition, the CPU 121a is configured to read a recipe such as the process recipe from the memory 121c in accordance with an operation command inputted from the input/output device 122. In accordance with the contents of the read recipe, the CPU 121a may be configured to control various operations such as flow rate adjusting operations for various gases by the MFCs 312, 322, 332, 512, 522 and 532, opening and closing operations of the valves 314, 324, 334, 514, 524 and 534, an opening and closing operation of the APC valve 243, a pressure adjusting operation by the APC valve 243 based on the pressure sensor 245, a temperature adjusting operation by the heater 207 based on the temperature sensor 263, a start and stop of the vacuum pump 246, an operation of adjusting a rotation and a rotation speed of the boat 217 by the rotator 267, an elevating and lowering operation of the boat 217 by the boat elevator 115 and an operation of transferring and accommodating the wafer 200 into the boat 217.

The controller 121 may be embodied by installing the above-described program stored in an external memory 123 into a computer. For example, the external memory 123 may include a magnetic tape, a magnetic disk such as a flexible disk and a hard disk, an optical disk such as a CD and a DVD, a magneto-optical disk such as an MO and a semiconductor memory such as a USB memory and a memory card. The memory 121c or the external memory 123 may be embodied by a non-transitory computer readable recording medium. Hereafter, the memory 121c and the external memory 123 are collectively or individually referred to as a “recording medium”. In the present specification, the term “recording medium” may refer to the memory 121c alone, may refer to the external memory 123 alone, and may refer to both of the memory 121c and the external memory 123. Instead of the external memory 123, a communication structure such as the Internet and a dedicated line may be used for providing the program to the computer.

### (2) Processing Step

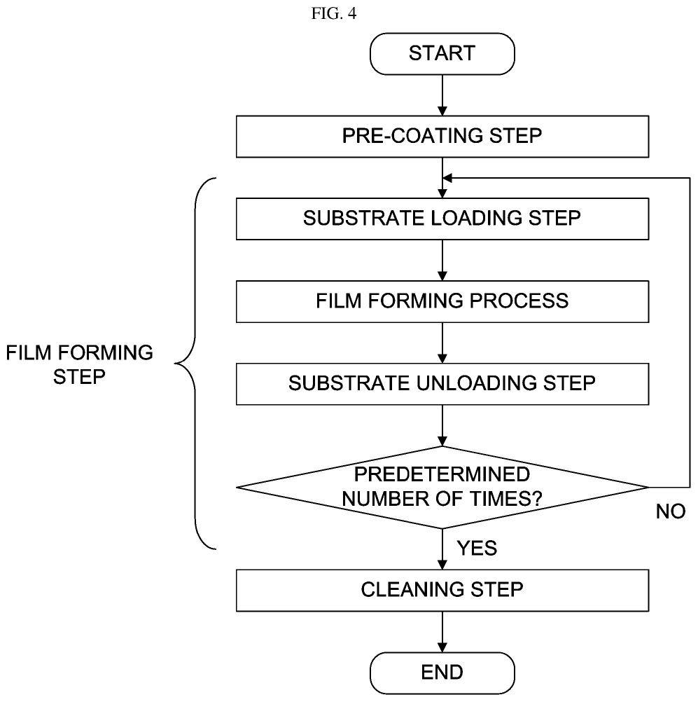

Hereinafter, as a part of a manufacturing process of a semiconductor device, an example of a series of process sequences including a film forming process of forming a film on the wafer 200 serving as the substrate will be described mainly with reference to FIGS. 4 to 6, and FIGS. 7A to 7D. The process sequences are performed by using the substrate processing apparatus 10 described above. In the following description, operations of the components constituting the substrate processing apparatus 10 are controlled by the controller 121.

The manufacturing process of the semiconductor device according to the embodiments of the present disclosures may include: (a) supplying the first process gas to the process vessel; (b) supplying the second process gas different from the first process gas to the process vessel; (c) supplying the third process gas different from each of the first process gas and the second process gas to the process vessel; (d) performing a first cycle X times, the first cycle comprising performing (a) and (b); (e) performing a second cycle Y times, the second cycle comprising performing (d) and (c); and (f) changing X in a next execution of the second cycle according to the number of previous executions of the second cycle in (e).

In the present specification, the term “wafer” may refer to “a wafer itself”, may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, may refer to “a surface of a predetermined layer or a film formed on a wafer”. In the present specification, the term “substrate” and “wafer” may be used as substantially the same meaning.

### Film Forming Step

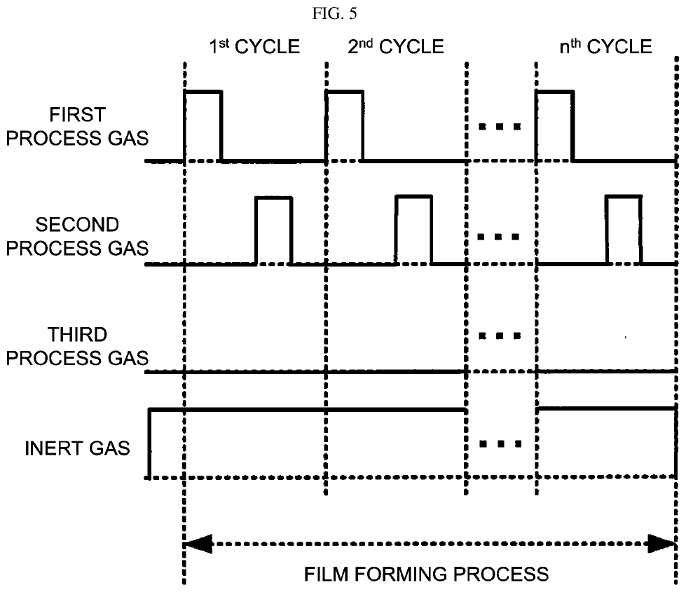

First, a film forming step in which the wafer 200 is transferred (loaded) into the process furnace 202 and a film is formed on the wafer 200 will be described with reference to FIGS. 4 and 5.

### Substrate Loading Step

The wafers 200 are charged (transferred) into the boat 217 (wafer charging step). After the boat 217 is charged with the wafers 200, as shown in FIG. 1, the boat 217 charged with the wafers 200 is elevated by the boat elevator 115 and loaded (transferred) into the process chamber 201 (boat loading step). With the boat 217 loaded, the seal cap 219 seals the lower end opening of the outer tube 203 via the O-ring 220b.

The vacuum pump 246 vacuum-exhausts the inner atmosphere of the process chamber 201 such that the inner pressure of the process chamber 201 (that is, a pressure in a space in which the wafers 200 are accommodated) reaches and is maintained at a desired pressure (vacuum degree). Meanwhile, the inner pressure of the process chamber 201 is measured by the pressure sensor 245, and the APC valve 243 is feedback-controlled based on measured pressure information by the pressure sensor 245 (pressure adjusting step). Further, the heater 207 heats the process chamber 201 such that the inner temperature of the process chamber 201 reaches and is maintained at a desired temperature. Meanwhile, the amount of the current supplied to the heater 207 is feedback-controlled based on the temperature information detected by the temperature sensor 263 such that the desired temperature distribution of the inner temperature of the process chamber 201 is obtained (temperature adjusting step). In addition, the rotator 267 starts rotating the wafer 200. The vacuum pump 246 continuously vacuum-exhausts the inner atmosphere of the process chamber 201, the heater 207 continuously heats the wafer 200 and the rotator 267 continuously rotates the wafer 200 until at least a processing of the wafer 200 is completed.

### Film Forming Process

The film forming process includes the following steps, that is, from a first process gas supply step to a returning to an atmospheric pressure step described below.

### First Process Gas Supply Step S10

The valve 314 is opened to supply the first process gas into the gas supply pipe 310. A flow rate of the first process gas supplied into the gas supply pipe 310 is adjusted by the MFC 312. The first process gas whose flow rate is adjusted is then supplied into the process chamber 201 through the gas supply holes 410a of the nozzle 410, and is exhausted through the exhaust pipe 231. Simultaneously with a supply of the first process gas, the valve 514 is opened to supply the inert gas such as the N₂ gas into the gas supply pipe 510. A flow rate of the inert gas supplied into the gas supply pipe 510 is adjusted by the MFC 512. The inert gas whose flow rate is adjusted is then supplied into the process chamber 201 together with the first process gas, and is exhausted through the exhaust pipe 231. Further, in the present step, in order to prevent the first process gas from entering the nozzles 420 and 430, the valves 524 and 534 are opened to supply the inert gas into the gas supply pipes 520 and 530. The inert gas is then supplied into the process chamber 201 through the gas supply pipes 320 and 330 and the nozzles 420 and 430, and is exhausted through the exhaust pipe 231.

In the present step, for example, the APC valve 243 is appropriately adjusted (or controlled) such that the inner pressure of the process chamber 201 can be set to a pressure within a range from 1 Pa to 3,990 Pa. For example, a supply flow rate of the first process gas controlled by the MFC 312 can be set to a flow rate within a range from 0.1 slm to 2.0 slm. For example, cach supply flow rate of the inert gas controlled by each of the MFCs 512, 522 and 532 can be set to a flow rate within a range from 0.1 slm to 20 slm. In the present step, for example, a temperature of the heater 207 can be set such that a temperature of the wafer 200 reaches and is maintained at a temperature within a range from 300° C. to 650° C. For example, a supply time (time duration) of supplying the first process gas to the wafer 200 is set to a time within a range from 0.01 second to 30 seconds. In the present specification, a notation of a numerical range such as “from 1 Pa to 3,990 Pa” means that a lower limit and an upper limit are included in the numerical range. Therefore, for example, the numerical range “from 1 Pa to 3,990 Pa” means a range equal to or higher than 1 Pa and equal to or lower than 3,990 Pa. The same also applies to other numerical ranges described herein.

In the present step, the first process gas is supplied to the wafers 200. As the first process gas, for example, a gas containing titanium (Ti) serving as a metal element may be used. For example, a gas containing a halogen element such as titanium tetrafluoride (TiF₄) gas, titanium tetrachloride (TiCl₄) gas and titanium tetrabromide (TiBr₄) gas may be used as the first process gas. As the first process gas, for example, one or more of the gases exemplified above may be used.

### Purge Step S11

After a predetermined time has elapsed from the supply of the first process gas, the valve 314 is closed to stop the supply of the first process gas. In the present step, with the APC valve 243 of the exhaust pipe 231 open, the vacuum pump 246 vacuum-exhausts the inner atmosphere of the process chamber 201 to remove the first process gas (which remains unreacted or already contributed to a formation of the film) remaining in the process chamber 201 from process chamber 201. Further, in the present step, by maintaining the valves 514, 524 and 534 open, the inert gas may be continuously supplied into the process chamber 201. In addition, the inert gas serves as a purge gas, which improves an efficiency of removing the first process gas (which remains unreacted or already contributed to the formation of the film) remaining in the process chamber 201 out of the process chamber 201.

### Second Process Gas Supply Step S12

After a predetermined time has elapsed from a start of the purge step S11, the valve 324 is opened to supply the second process gas into the gas supply pipe 320. A flow rate of the second process gas supplied into the gas supply pipe 320 is adjusted by the MFC 322. The second process gas whose flow rate is adjusted is then supplied into the process chamber 201 through the gas supply holes 420a of the nozzle 420, and is exhausted through the exhaust pipe 231. In the present step, simultaneously with a supply of the second process gas, the valve 524 is opened to supply the inert gas into the gas supply pipe 520. In the present step, in order to prevent the second process gas from entering the nozzles 410 and 430, the valves 514 and 534 are opened to supply the inert gas into the gas supply pipes 510 and 530.

In the present step, for example, the APC valve 243 is appropriately adjusted (or controlled) such that the inner pressure of the process chamber 201 can be set to a pressure within a range from 1 Pa to 3,990 Pa. For example, a supply flow rate of the second process gas controlled by the MFC 322 can be set to a flow rate within a range from 0.1 slm to 30 slm. For example, cach supply flow rate of the inert gas controlled by each of the MFCs 512, 522 and 532 can be set to a flow rate within a range from 0.1 slm to 20 slm For example, a supply time (time duration) of supplying the second process gas to the wafer 200 is set to a time within a range from 0.01 second to 30 seconds.

In the present step, the second process gas is supplied to the wafers 200. As the second process gas, for example, a nitrogen-containing gas, that is, a gas containing nitrogen (N) serving as the Group 15 element may be used. As the nitrogen-containing gas, for example, a hydrogen nitride-based gas such as ammonia (NH₃) gas, diazene (N₂H₂) gas, hydrazine (N₂H₄) gas and N₃H₈ gas may be used. As the second process gas, for example, one or more of the gases exemplified above may be used.

### Purge Step S13

After a predetermined time has elapsed from the supply of the second process gas, the valve 324 is closed to stop the supply of the second process gas. Then, the second process gas (which remains unreacted or already contributed to the formation of the film) remaining in the process chamber 201 is removed from the process chamber 201 in substantially the same manners as in the purge step S11 described above.

### Performing a Predetermined Number of Times

By performing a cycle (in which the step S10 to the step S13 described above are sequentially performed in this order) at least once (that is, a predetermined number of times (n times)), it is possible to form a film with a predetermined thickness on the wafer 200. It is preferable that the cycle described above is repeatedly performed a plurality number of times. According to the present embodiments, for example, a titanium nitride (TiN) film is formed on the wafer 200 as a film containing the metal element and the Group 15 element. In FIG. 5, notations such as “1^{st} CYCLE”, “2^{nd} CYCLE” and “n^{th} CYCLE” refer to a “first execution” of the cycle, a “second execution” of the cycle and an “n^{th} execution” of the cycle, respectively.

### After-Purge Step and Returning to Atmospheric Pressure Step

The inert gas is supplied into the process chamber 201 through each of the gas supply pipes 510, 520 and 530, and is exhausted through the exhaust pipe 231. The inert gas serves as the purge gas, and the inner atmosphere of the process chamber 201 is purged with the inert gas. Thus, a residual gas in the process chamber 201 and reaction by-products remaining in the process chamber 201 are removed from the process chamber 201 (after-purge step). Thereafter, the inner atmosphere of the process chamber 201 is replaced with the inert gas (substitution by inert gas), and the inner pressure of the process chamber 201 is returned to a normal pressure (atmospheric pressure) (returning to the atmospheric pressure step).

### Substrate Unloading Step

Thereafter, the seal cap 219 is lowered by the boat elevator 115 and the lower end of the outer tube 203 is opened. The boat 217 with the processed wafers 200 charged therein (that is, the wafers 200 with a predetermined film formed thereon) is unloaded out of the outer tube 203 through the lower end of the outer tube 203 (boat unloading step). Then, the processed wafers 200 are discharged (transferred) out of the boat 217 (wafer discharging step).

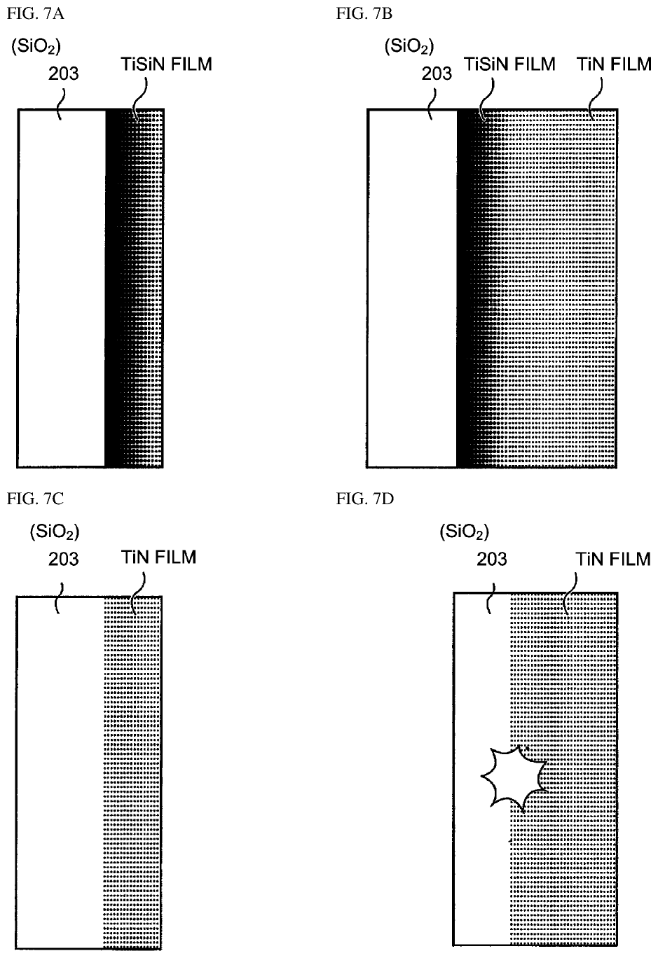

When the film forming step described above is performed, as shown in FIG. 7C, at an inner side of the process vessel, a deposit including the film such as the TiN film formed on the wafer 200 may adhere to and accumulate on a surface of a component in the process vessel, for example, an inner wall of the outer tube 203, the inner wall of the inner tube 204, outer surfaces of the nozzles 410, 420 and 430, inner surfaces of the gas supply holes 410a, the gas supply holes 420a and the gas supply holes 430a, an inner surface of the manifold 209, a surface of the boat 217 and the upper surface of the seal cap 219. Further, as shown in FIG. 7D, when an amount of the deposit, that is, an accumulative thickness of the film is too thick, the deposit may peel off and an amount of particles generated thereby may increase rapidly. Therefore, a cleaning step is performed to remove the deposit accumulated in the process vessel before the accumulative thickness of the film (the amount of the deposit) reaches a predetermined thickness (predetermined amount) before the deposit peels off or falls off.

### Cleaning Step

In the cleaning step, an empty boat 217 (that is, the boat 217 without the wafers 200) charged (loaded) therein is transferred (loaded) into the process vessel. Then, a cleaning gas is supplied into the process chamber 201, and is exhausted through the exhaust pipe 231. As a result, the deposit accumulated on the surface of the component in the process chamber 201 (for example, the deposit accumulated on the inner side of the process vessel) is removed.

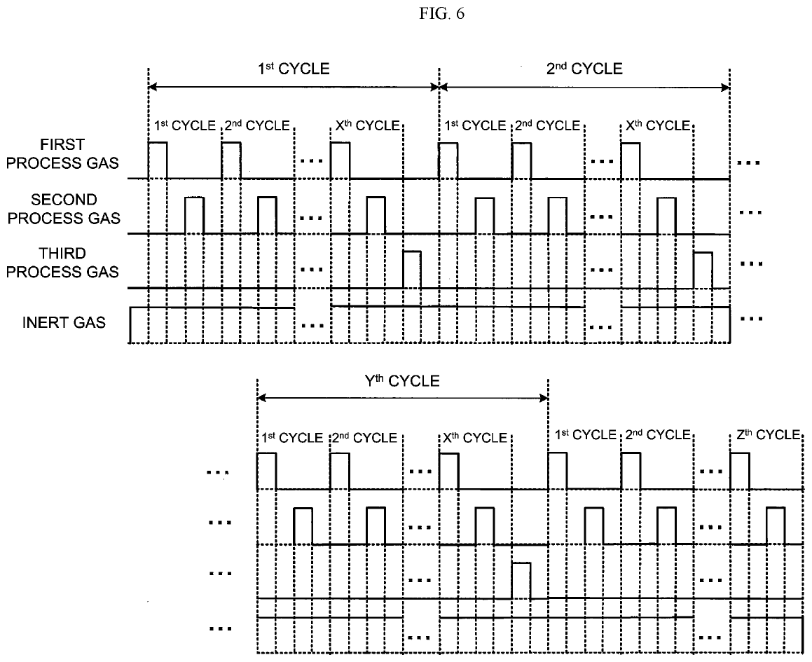

After the cleaning step, a pre-coating step is performed to perform a pre-coating process on the inner side of the process vessel. When the film forming process is performed without the pre-coating process, the thickness of the film formed on the wafer 200 may be thinner than a target thickness of the film. Such phenomenon may also be referred to as a “film thickness drop phenomenon” in which the thickness of the film drops. This is probably because a state in the process vessel after the cleaning process is different from a state in the process vessel when the film forming process is repeatedly performed. For example, the process gas is consumed on the surface of the component inside the process vessel when performing the film forming process, and thereby, an amount of the process gas supplied to the surface of the wafer 200 may be insufficient. By performing the pre-coating process after the cleaning process and before performing the film forming process, it is possible to suppress an occurrence of the film thickness drop phenomenon and it is also possible to stabilize the thickness of the film formed on the wafer 200. Hereinafter, a series of operations in the pre-coating step will be described with reference to FIG. 6.

### Pre-Coating Step

After the cleaning step is completed and before the film forming step is performed, with the empty boat 217 loaded into the process vessel, a pre-coating film is formed on the inner side of the process vessel, that is, on the surface of the component in the process vessel, for example, the inner wall of the outer tube 203, the inner wall of the inner tube 204, the outer surfaces of the nozzles 410, 420 and 430, the inner surfaces of the gas supply holes 410a, the gas supply holes 420a and the gas supply holes 430a, the inner surface of the manifold 209, the surface of the boat 217 (that is, the empty boat 217) and the upper surface of the seal cap 219. That is, the pre-coating process is performed by a coating method in which the inner side (inner wall) of the process vessel is coated with the pre-coating film. Alternatively, the pre-coating process may be performed while the boat 217 is unloaded from the process vessel.

### First Process Gas Supply Step S20

The first process gas is supplied into the process chamber 201, that is, inside the process vessel, in substantially the same manners as in the step S10 described above. That is, the valve 314 is opened to supply the first process gas into the gas supply pipe 310. The flow rate of the first process gas supplied into the gas supply pipe 310 is adjusted by the MFC 312. The first process gas whose flow rate is adjusted is then supplied into the process chamber 201 through the gas supply holes 410a of the nozzle 410, and is exhausted through the exhaust pipe 231. Simultaneously with the supply of the first process gas, the valve 514 is opened to supply the inert gas such as the N₂ gas into the gas supply pipe 510. The flow rate of the inert gas supplied into the gas supply pipe 510 is adjusted by the MFC 512. The inert gas whose flow rate is adjusted is then supplied into the process chamber 201 together with the first process gas, and is exhausted through the exhaust pipe 231. Further, in the present step, in order to prevent the first process gas from entering the nozzles 420 and 430, the valves 524 and 534 are opened to supply the inert gas into the gas supply pipes 520 and 530. The inert gas is then supplied into the process chamber 201 through the gas supply pipes 320 and 330 and the nozzles 420 and 430, and is exhausted through the exhaust pipe 231.

That is, in the present step, the first process gas is supplied into process chamber 201. As the first process gas in the present step, for example, the gas containing titanium (Ti) serving as the metal element may be used. For example, the gas containing the halogen element may be used as the first process gas in the present step.

### Purge Step S21

Then, the first process gas (which remains unreacted or already contributed to formation of the film) remaining in the process chamber 201 is removed from the process chamber 201 in substantially the same manners as in the purge step S11 described above.

### Second Process Gas Supply Step S22

The second process gas is supplied into the process chamber 201 in substantially the same manners as in the step S12 described above. That is, after a predetermined time has elapsed from a start of the purge step S21, the valve 324 is opened to supply the second process gas into the gas supply pipe 320. The flow rate of the second process gas supplied into the gas supply pipe 320 is adjusted by the MFC 322. The second process gas whose flow rate is adjusted is then supplied into the process chamber 201 through the gas supply holes 420a of the nozzle 420, and is exhausted through the exhaust pipe 231. In the present step, simultaneously with the supply of the second process gas, the valve 524 is opened to supply the inert gas into the gas supply pipe 520. In the present step, in order to prevent the second process gas from entering the nozzles 410 and 430, the valves 514 and 534 are opened to supply the inert gas into the gas supply pipes 510 and 530.

In the present step, the second process gas is supplied into process chamber 201. As the second process gas in the present step, for example, the gas containing nitrogen (N) serving as the Group 15 element may be used.

### Purge Step S23

Then, the second process gas (which remains unreacted or already contributed to the formation of the film) remaining in the process chamber 201 is removed from the process chamber 201 in substantially the same manners as in the purge step S13 described above.

### Performing a Predetermined Number of Times S24

By performing a cycle (that is, the first cycle in which the step S20 to the step S23 described above are sequentially performed in this order) a predetermined number of times (X times, where X is an integer equal to or greater than 1), it is possible to form a pre-coating film with a predetermined thickness on surfaces such as the inner wall of the process vessel. It is preferable that the first cycle described above is repeatedly performed a plurality number of times. In FIG. 6, notations such as “1^{st} CYCLE”, “2^{nd} CYCLE” and “X^{th} CYCLE” refer to a “first execution” of the first cycle, a “second execution” of the first cycle and an “X^{th} execution” of the first cycle, respectively. The same also applies to other drawings.

In other words, in a state in which the wafer 200 is not present in the process vessel, the first cycle in which the steps S20 to S23 similar to the steps S10 to S13 in the film forming step described above are sequentially performed in this order is performed the predetermined number of times (X times, where X is an integer equal to or greater than 1). The process sequences and the process conditions in each step of the pre-coating step are substantially the same as the process sequences and the process conditions in each step of the film forming step described above, except that each gas is supplied into the process vessel instead of being supplied to the wafer 200.

### Third Process Gas Supply Step S25

Then, after the step S24 is performed, that is, the first cycle in which the steps S20 to S23 are sequentially performed in this order is performed the predetermined number of times (X times, where X is an integer equal to or greater than 1), the third process gas is supplied into the process chamber 201. That is, the valve 334 is opened to supply the third process gas into the gas supply pipe 330. The flow rate of the third process gas supplied into the gas supply pipe 330 is adjusted by the MFC 332. The third process gas whose flow rate is adjusted is then supplied into the process chamber 201 through the gas supply holes 430a of the nozzle 430, and is exhausted through the exhaust pipe 231. In the present step, simultaneously with a supply of the third process gas, the valve 534 is opened to supply the inert gas into the gas supply pipe 530. In the present step, in order to prevent the third process gas from entering the nozzles 410 and 420, the valves 514 and 524 are opened to supply the inert gas into the gas supply pipes 510 and 520.

In the present step, for example, the APC valve 243 is appropriately adjusted (or controlled) such that the inner pressure of the process chamber 201 can be set to a pressure within a range from 1 Pa to 3,990 Pa. For example, a supply flow rate of the third process gas controlled by the MFC 332 can be set to a flow rate within a range from 0.1 slm to 10 slm. For example, each supply flow rate of the inert gas controlled by each of the MFCs 512, 522 and 532 can be set to a flow rate within a range from 0.1 slm to 20 slm For example, a supply time (time duration) of supplying the third process gas to the wafer 200 is set to a time within a range from 0.01 second to 60 seconds.

In the present step, the third process gas is supplied into process chamber 201. As the third process gas, for example, a silicon-containing gas, that is, a gas containing silicon (Si) serving as the Group 14 element may be used. As the silicon-containing gas, for example, a silane-based gas such as monosilane (SiH₄) gas, disilane (Si₂H₆) gas and trisilane (Si₃H₈) gas may be used. As the third process gas, for example, one or more of the gases exemplified above may be used.

### Purge Step S26

After a predetermined time has elapsed from the supply of the third process gas, the valve 334 is closed to stop the supply of the third process gas. Then, the third process gas (which remains unreacted or already contributed to the formation of the film) remaining in the process chamber 201 is removed from the process chamber 201 in substantially the same manners as in the purge step S21 and the purge step S23 described above.

### Performing a Predetermined Number of Times S27

By performing a cycle (that is, the second cycle in which the step S24 to the step S26 described above are sequentially performed in this order) a predetermined number of times (Y times, where Y is an integer equal to or greater than 1), that is, by performing the second cycle (in which the first cycle in which the steps S20 to S23 are sequentially performed in this order is performed the predetermined number of times (X times, where X is an integer equal to or greater than 1) and then the steps S25 and S26 are performed) the predetermined number of times (Y times, where Y is an integer equal to or greater than 1), it is possible to form the film with a predetermined thickness containing the first element, the second element and the third element. In FIG. 6, notations such as “1^{st} CYCLE”, “2^{nd} CYCLE” and “Y^{th} CYCLE” refer to a “first execution” of the second cycle, a “second execution” of the second cycle and a “Y^{th} execution” of the second cycle, respectively. The same also applies to other drawings.

In a manner described above, after the first process gas containing the first element and the second process gas containing the second element are alternately and repeatedly supplied into the process chamber 201, the third process gas containing the third element is supplied. Thereby, the film of a predetermined thickness containing the first element, the second element and the third element is formed as the pre-coating film on a surface of quartz such as the inner wall of the process vessel. For example, a titanium silicon nitride (TiSiN) film containing titanium (Ti) serving as the metal element, nitrogen (N) serving as the Group 15 clement and silicon (Si) serving as the Group 14 element is formed. Therefore, since an adhesion to the component such as the inner wall of the process vessel can be improved, the film is less likely to peel off from the component such as the inner wall of the process vessel. Further, it is possible to reduce a surface roughness of an initial film of the pre-coating film.

For example, in the present step, a ratio of X and Y can be changed by changing the number of times X according to the number of times the second cycle has actually been performed so far within the entire period of performing the second cycle Y times. Thereby, a film can be formed on the component such as the inner wall of the process vessel in a manner that a ratio of the first element serving as the metal element and the third element serving as the Group 14 clement vary according to the ratio of X and Y.

Specifically, the number of times X (which is the number of times of performing the first cycle in which the steps S20 to S23 are sequentially performed) is increased according to the number of previous executions of the second cycle (i.e., the number of times the second cycle has actually been performed so far) within the entire period of performing the second cycle Y times in the present step. For example, X is increased whenever the number of previous executions of the second cycle are increased by a predetermined number. By increasing the number of times X according to the number of previous executions of the second cycle, it is possible to form a film in which a concentration of the third element contained in the third process gas is reduced each time X is increased. That is, it is possible to control the concentration of the third clement to vary (change) stepwise as it goes from a base of the pre-coating film to the surface of the pre-coating film on the surface of the component such as the inner wall of the process vessel.

That is, by changing the number of times X according to the number of previous executions of the second cycle, it is possible to form a film with a different composition. Further, it is possible to form a film whose ratio of the metal element contained in the first process gas to the Group 14 element contained in the third process gas varies according to the ratio of X and Y on the surface of the component such as the inner wall of the process vessel.

Further, a supply amount of the third process gas in the step S25 may be changed according to the number of previous executions of the second cycle in the step S27. The supply amount of the third process gas is calculated by a product of the supply flow rate of the third process gas and the supply time of the third process gas. That is, one or both of the supply time and the supply flow rate of the third process gas in the step S25 is changed according to the number of previous executions of the second cycle in the step S27. Even in such a case, it is possible to control the concentration of the third element to vary (change) stepwise as it goes from the base of the pre-coating film to the surface of the pre-coating film.

For example, the supply time of the third process gas is changed such that a relationship is established where a supply time TI of the third process gas before the number of previous executions of the second cycle reaches a predetermined number of times is greater than the supply time T2 of the third process gas after the number of previous executions of the second cycle reaches the predetermined number of times. In a manner described above, by shortening the supply time T2 of the third process gas after the number of previous executions of the second cycle reaches the predetermined number of times as compared with the supply time Tl of the third process gas before the number of previous executions of the second cycle reaches the predetermined number of times, it is possible to reduce a content of silicon on a surface of the TiSiN film formed in the present step where the second cycle is performed Y times. Further, it is possible to adjust the surface of the TiSiN film to be substantially the same as the TiN film. In addition, by shortening the supply time of the third process gas, it is possible to shorten a processing time of the pre-coating step, and it is also possible to improve a throughput in the manufacturing process of the semiconductor device.

For example, there may be a case where a single TiN film is not formed by performing the first cycle a single time and X is continuously changed in each execution of the second cycle. In this case, the supply amount of the third process gas changes before a single TiN layer is formed, and thus it may not be possible to form a pre-coating layer with a desired composition. By changing the number of times X according to the number of previous executions of the second cycle and controlling it stepwise, it is possible to form the pre-coating layer with the desired composition. That is, it is possible to change the composition for each layer.

Specifically, as shown in FIG. 7A, a TiSiN film is formed in contact with a surface region of the quartz. Herein, the lattice constant of a portion of the TiSiN film contacting the quartz is similar to that of quartz (SiO₂). The TiSiN film is formed on the surface of the quartz at such locations as the inner wall of the outer tube 203 such that its content of silicon (also referred to as a “silicon content” or a “silicon concentration”) varies according to the ratio of X and Y from a base region of the pre-coating film (on the surface region of the quartz) to a surface of the pre-coating film. That is, when the gas containing titanium (Ti) as the metal element is used as the first process gas, the gas containing nitrogen (N) as the Group 15 element is used as the second process gas and the gas containing silicon (Si) as the Group 14 element is used as the third process gas, the TiSiN film whose ratio of titanium as the metal element and silicon as the Group 14 clement is different between the base region of the pre-coating film and the surface region of the pre-coating film can be formed on the surface of the quartz at such locations as the inner wall of the outer tube 203.

### Performing a Predetermined Number of Times S28

By performing a cycle (that is, a third cycle in which the step S20 to the step S23 described above are sequentially performed in this order) a predetermined number of times (Z times, where Z is an integer equal to or greater than 1), a film containing the same first element and the same second element as the film formed on the wafer 200 can be formed on a surface of the film containing the first element, the second element and the third element and serving as the pre-coating film. In FIG. 6, notations such as “1^{st} CYCLE”, “2^{nd} CYCLE” and “Z^{th} CYCLE” refer to a “first execution” of the third cycle, a “second execution” of the third cycle and a “Z^{th} execution” of the third cycle, respectively. The same also applies to other drawings.

Specifically, as shown in FIG. 7B, on a surface of the TiSiN film serving as the pre-coating film with varying content of silicon, a TiN film whose lattice constant is similar to that of the TiN film can be formed on the wafer 200 with the same constituents as the TiN film. The number of times Z is not changed even when the number of previous executions of the second cycle within the entire period of performing the second cycle Y times is increased by the predetermined number. By performing the third cycle (in which the step S20 to the step S23 described above are sequentially performed in this order) a predetermined number of times (Z times, where Z is an integer equal to or greater than 1) in a manner described above, it is possible to cover the surface of the pre-coating film with the TiN film. By covering the surface of the pre-coating film with the TiN film, it is possible to prevent an exposure of the TiSiN film, and it is also possible to improve a film process uniformity for each substrate processing.

That is, a film such as the TiSiN film containing titanium (Ti) serving as the first element (metal element), nitrogen (N) serving as the second element (Group 15 element) and silicon (Si) serving as the third element (Group 14 element) is formed on the surface of the quartz such as the inner wall of the process vessel, and the TiN film is formed on the surface of the pre-coating film.

Therefore, it is possible to form a film whose composition is changed from the film containing titanium (Ti), nitrogen (N) and silicon (Si) (that is, the film containing the first element, the second element and the third element) to the film containing titanium (Ti) and nitrogen (N) (that is, the film containing the first element and the second element). In a manner described above, by employing the TiN film as the outermost surface of the pre-coating film, it is possible to uniformize a consumption amount of the process gas for each film forming of the TiN film on the wafers 200, and it is also possible to uniformize a process quality therefor.

For example, depending on whether the surface of the process vessel of the pre-coating film is the TiN film or the TiSiN film, the amount of the process gas consumed on the surface of the process vessel when performing the film forming process on the wafer 200 may change. Thereby, for example, an adsorption amount of the first process gas serving as one of the process gases may change between the TiN film and the TiSiN film. That is, the first process gas may be consumed by component such as the inner wall of the process vessel, and thus an amount of the first process gas supplied to the wafer 200 may change. As a result, a quality of the TiN film formed on the wafer 200 (such as a thickness, a crystallinity, a continuity and a surface roughness of the TiN film) may change.

According to the present embodiments, the TiSiN film containing silicon and serving as the base region of the pre-coating film is formed on the surface region of the process vessel, and the TiN film whose content of silicon is as small as the surface region of the pre-coating film and whose outermost surface is free of silicon is formed on the TiSiN film.

That is, the base region of the pre-coating film (on the surface region of the process vessel) is the TiSiN film containing silicon contained in the quartz (SiO₂) serving as the material of the process vessel. Thereby, since the adhesion to the component such as the inner wall of the process vessel can be improved, the film is less likely to peel off from the component such as the inner wall of the process vessel. Further, it is possible to reduce the surface roughness of the initial film of the pre-coating film. In addition, the precoating step may employ the process gases for the film forming step without containing any elements other than those contained in the film (TiN film) formed on the wafer 200. Thereby, it is possible to perform the pre-coating step without adding a gas supplier for the pre-coating step, and it is also possible to reduce a cost of the substrate processing apparatus.

In addition, since the TiN film that is the same as the film to be formed on the wafer 200 is employed as the outermost surface of the pre-coating film, it is possible to uniformize the consumption amount of the process gas for each film forming (each batch process) of the TiN film on the wafers 200, and it is also possible to uniformize the process quality therefor.

For example, in the first half of the pre-coating step, X is set to 1. After performing the second cycle a predetermined number of times with X set to 1, X is changed to 3. After performing the second cycle a predetermined number of times with X set to 3, X is changed to 5. In a manner described above, the number of times X is gradually increased. As a result, a highly concentrated silicon film is provided at the base region of the pre-coating film, and a TiN film free of silicon is provided at the outermost surface of the pre-coating film.

By performing the series of operations described above, the pre-coating step is completed. By the pre-coating step described above, it is possible to suppress a generation of the particles in the process chamber 201. As a result, it is possible to improve the process quality such as characteristics of the film formed on the wafer 200.

### Empty Boat Unloading Step

After the pre-coating process is completed, the seal cap 219 is lowered by the boat elevator 115 and the lower end of the manifold 209 is opened. Then, the empty boat 217 is unloaded out of the outer tube 203 through the lower end of the manifold 209 (empty boat unloading step).

### (3) Effects According to Present Embodiments

According to the present embodiments, it is possible to obtain one or more of the following effects.
(a) It is possible to suppress the generation of the particles. That is, it is possible to suppress the generation of the particles due to a film peeling inside the process chamber (inside the process vessel).
(b) It is possible to improve the throughput in the manufacturing process of the semiconductor device.
(c) It is possible to improve the process quality such as the characteristics of the film formed on the wafer 200, and it is also possible to uniformize the process quality.

### (4) Other Embodiments of Present Disclosure

While the technique of the present disclosure is described in detail by way of the embodiments described above, the technique of the present disclosure is not limited thereto. The technique of the present disclosure may be modified in various ways without departing from the scope thereof.

### First Modified Example

FIG. 8 is a diagram schematically illustrating a modified example of a gas supply in the pre-coating step according to the embodiments of the technique of the present disclosure. According to the present modified example, a step of supplying a fourth process gas different from the first process gas, different from the second process gas and different from the third process gas to the process vessel is further performed.

That is, in the second cycle in the pre-coating step according to the present modified example, after performing the first cycle of performing the steps S20 to S23 X times in the step S24 described above, a supply of the fourth gas and a purge of the fourth gas are further performed before the step S25 and the step S26 are performed. After performing the second cycle further including the supply of the fourth gas and the purge of the fourth gas Y times, the supply of the fourth gas and the purge of the fourth gas are further performed. Then, the step S28 described above is performed. That is, the fourth process gas is supplied after the step S24 (that is, after the first cycle is performed X times) and also supplied after the step S27 (that is, after the second cycle according to the present modified example is performed Y times). Alternatively, the fourth process gas may be supplied either after the step S24 or after the step S27 (that is, after the second cycle according to the embodiments described above is performed Y times). In the present modified example, the number of times X is also changed according to the number of previous executions of the second cycle within the entire period of performing the second cycle Y times. Thereby, it is possible to improve the process quality such as the characteristics of the film formed on the wafer 200 while suppressing a peeling of the pre-coating film.

In the present modified example, as the fourth process gas, for example, an oxygen-containing gas (also referred to as an “oxidizing gas”) such as oxygen (O₂) gas, ozone (O₃) gas, plasma-excited O₂ gas (O₂* gas), a mixed gas of the O₂ gas and hydrogen (H₂) gas, water vapor (H₂O) gas, hydrogen peroxide (H₂O₂) gas, nitrous oxide (N₂O) gas, nitrogen monoxide (NO) gas, nitrogen dioxide (NO₂) gas, carbon monoxide (CO) gas and carbon dioxide (CO₂) gas may be used. As the fourth process gas, for example, one or more of the gases exemplified above may be used. By oxidizing the pre-coating film while forming the pre-coating film in a manner described above, it is possible to reduce a stress of the pre-coating film, and it is also possible to suppress the peeling of the pre-coating film. In addition, by supplying the oxygen-containing gas while forming the pre-coating film, it is possible to form split layers of crystals such as TiN and TiSiN. Thereby, it is possible to suppress an abnormal growth of the crystals, and it is also possible to reduce the surface roughness of the pre-coating film.

### Second Modified Example

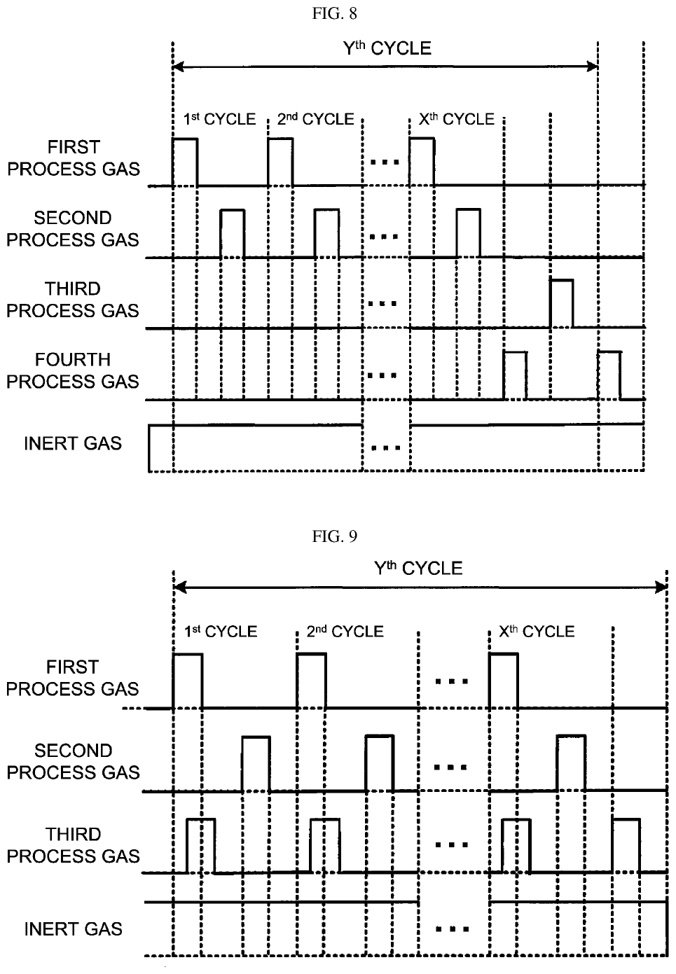

FIG. 9 is a diagram schematically illustrating another modified example of the gas supply in the pre-coating step according to the embodiments of the technique of the present disclosure. According to the present modified example, when the first process gas is supplied in the pre-coating step, the third process gas is partially supplied in parallel. That is, in the first cycle according to the present modified example, the supply of the first process gas, a simultaneous supply of the first process gas and the third process gas, the supply of the third process gas and a purge of the third process gas, and the supply of the second process gas and a purge of the second process gas are sequentially performed. In the second cycle according to the present modified example, the first cycle according to the present modified example is performed X times and then the supply of the third process gas and the purge of the third process gas is performed. The second cycle according to the present modified example is performed Y times. Then, the step S28 is performed. In the present modified example, the number of times X is also changed according to the number of previous executions of the second cycle within the entire period of performing the second cycle Y times. Thereby, it is possible to improve the process quality such as the characteristics of the film formed on the wafer 200 while suppressing the peeling of the pre-coating film. It is also possible to improve a crystal continuity of the pre-coating film, and it is also possible to reduce the surface roughness of the pre-coating film.

### Third Modified Example

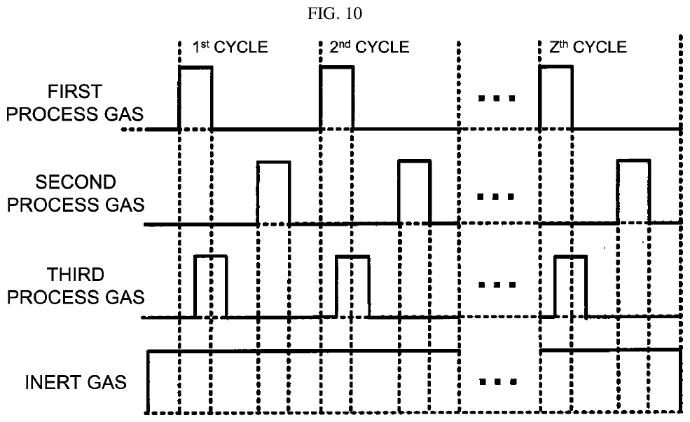

FIG. 10 is a diagram schematically illustrating a modified example of a gas supply in the film forming step according to the embodiments of the technique of the present disclosure. According to the present modified example, when the first process gas is supplied in the film forming step, the third process gas is partially supplied in parallel. That is, in the cycle of the film forming step according to the present modified example, the supply of the first process gas, the simultaneous supply of the first process gas and the third process gas, the supply of the third process gas and the purge of the third process gas, and the supply of the second process gas and the purge of the second process gas are sequentially performed. The cycle of the film forming step according to the present modified example is performed a predetermined number of times (Z times, where Z is an integer equal to or greater than 1). Thereby, it is possible to improve the crystal continuity on the surface of the pre-coating film, and it is also possible to reduce the surface roughness on the surface of the pre-coating film.

For example, after performing the pre-coating step in the second modified example described above, the film forming step in the third modified example described above may be performed. By performing a process described above from an initial stage of the pre-coating film in a manner described above, it is possible to improve the crystal continuity of the pre-coating film, and it is also possible to reduce the surface roughness of the pre-coating film.

For example, the embodiments described above are described by way of an example in which the gas containing silicon (Si) (which is the Group 14 element) serving as the third element is used as the third process gas in the pre-coating step. However, the technique of the present disclosure is not limited thereto. As the third process gas, for example, the O2 gas (which is the oxygen-containing gas) containing oxygen (O) (which is a Group 16 element) serving as the third element may be used. In such a case, a film containing titanium nitride oxide (TiON), that is, a film containing titanium (Ti) serving as the first element (metal element), nitrogen (N) serving as the second element (Group 15 element) and oxygen (O) serving as the third element (Group 16 element) is formed on the surface of the quartz such as the inner wall of the process vessel, and the TiN film is formed on the surface of the pre-coating film. Therefore, it is possible to form a film whose composition is changed from the film containing titanium (Ti), nitrogen (N) and oxygen (O) to the film containing titanium (Ti) and nitrogen (N).

For example, the embodiments described above are described by way of an example in which silicon (Si) is used as the Group 14 element. However, the technique of the present disclosure may also be applied when carbon (C) or germanium (Ge) is used as the Group 14 element.

For example, the embodiments described above are described by way of an example in which titanium (Ti) is used as the metal element contained in the first process gas. However, instead of the titanium, at least one among molybdenum (Mo), ruthenium (Ru), hafnium (Hf), zirconium (Zr) and tungsten (W) may be used as the metal element.

For example, the embodiments described above are described by way of an example in which a vertical batch type substrate processing apparatus configured to simultaneously process a plurality of substrates is used as the substrate processing apparatus to form the film. However, the technique of the present disclosure is not limited thereto. For example, the technique of the present disclosure may be preferably applied when a single wafer type substrate processing apparatus configured to process one or several substrates at a time is used to form the film.

It is preferable that the process recipe (that is, a program defining parameters such as the process sequences and the process conditions) used to form various films described above is prepared individually in accordance with the contents of the substrate processing such as a type of the film to be formed, a composition ratio of the film, a quality of the film, a thickness of the film, the process sequences and the process conditions of the substrate processing. That is, a plurality of process recipes are prepared. Then, when starting the substrate processing, an appropriate process recipe is preferably selected among the process recipes in accordance with the contents of the substrate processing. Specifically, it is preferable that the process recipes are stored (installed) in the memory 121c of the substrate processing apparatus in advance via an electric communication line or the recording medium (for example, the external memory 123) storing the process recipes prepared individually in accordance with the contents of the substrate processing. Then, when starting the substrate processing, the CPU 121a preferably selects the appropriate process recipe among the process recipes stored in the memory 121c of the substrate processing apparatus in accordance with the contents of the substrate processing. With such a configuration, various films of different types, different composition ratios, different qualities and different thicknesses may be universally formed with a high reproducibility using a single substrate processing apparatus. In addition, since a burden on an operator such as inputting the process sequences and the process conditions may be reduced, various substrate processes can be performed quickly while avoiding a misoperation of the apparatus.

Further, the technique of the present disclosure may be implemented by changing an existing process recipe stored in the substrate processing apparatus to a new process recipe. When changing the existing process recipe to the new process recipe, the new process recipe may be installed in the substrate processing apparatus via the electric communication line or the recording medium storing the process recipes. Alternatively, the existing process recipe already stored in the substrate processing apparatus may be directly changed to the new process recipe according to the technique of the present disclosure by operating the input/output device of the substrate processing apparatus.

The technique of the present disclosure is described in detail by way of the embodiments described above. However, the technique of the present disclosure is not limited thereto. For example, the embodiments described above may be appropriately combined.

According to some embodiments of the present disclosure, it is possible to suppress the generation of the particles.

What is claimed is:

1. A coating method comprising:
(a) supplying a first process gas to a process vessel;
(b) supplying a second process gas different from the first process gas to the process vessel;
(c) supplying a third process gas different from each of the first process gas and the second process gas to the process vessel;
(d) performing a first cycle X times, the first cycle comprising performing (a) and (b);
(e) performing a second cycle Y times, the second cycle comprising performing (d) and (c); and
(f) changing X in a next execution of the second cycle according to the number of previous executions of the second cycle in (e).

2. The coating method of claim 1, wherein, in (f), X in the next execution of the second cycle is increased according to the number of previous executions of the second cycle in (e).

3. The coating method of claim 1, wherein, in(f), X in the next execution of the second cycle in (e) is increased whenever the number of previous executions of the second cycle in (e) is increased by a predetermined number.

4. The coating method of claim 1, further comprising
(g) performing a third cycle Z times after (e) is performed, the third cycle comprising performing (a) and (b).

5. The coating method of claim 4, wherein, in (g), Z is not changed regardless of the number of previous executions of the second cycle in (e).

6. The coating method of claim 1, further comprising
(h) supplying a fourth process gas different from each of the first process gas, the second process gas and the third process gas to the process vessel,
wherein (h) is performed after at least one of (d) or (e) is performed.

7. The coating method of claim 1, wherein the first process gas contains a first element, the second process gas contains a second element, the third process gas contains a third element, and
wherein a film containing the first element, the second element and the third element is formed in (f), and a ratio of the first element and the third element on the film varies depending on a ratio of X and Y.

8. The coating method of claim 7, wherein at least a portion of an inner wall of the process vessel is constituted by quartz, the first element contains a metal element, the second element contains a Group 15 element and the third element contains a Group 14 element, and
wherein a film containing the metal element, the Group 15 element and the Group 14 element is formed on a surface of the quartz in (f).

9. The coating method of claim 8, wherein at least a portion of the metal element contains titanium, the Group 15 element contains nitrogen and the Group 14 element contains silicon, and
wherein a film containing titanium, nitrogen and silicon is formed on the surface of the quartz in (f).

10. The coating method of claim 7, wherein at least a portion of an inner wall of the process vessel is constituted by quartz, the first element contains a metal element, the second element contains a Group 15 element and the third element contains a Group 16 element, and
wherein a film containing the metal element, the Group 15 element and the Group 16 element is formed on a surface of the quartz in (f).

11. The coating method of claim 10, wherein the metal element contains titanium, the Group 15 element contains nitrogen and the Group 16 element contains oxygen, and
wherein a film containing titanium, nitrogen and oxygen is formed on the surface of the quartz in (f).

12. The coating method of claim 1, wherein, in (d), (c) is performed partially in parallel with (a) while (a) is being performed.

13. The coating method of claim 4, wherein, in (g), (c) is performed partially in parallel with (a) while (a) is being performed.

14. The coating method of claim 1, wherein a supply amount of the third process gas in (c) is changed according to the number of previous executions of the second cycle in (e).

15. The coating method of claim 1, wherein a supply time of the third process gas in (c) is changed according to the number of previous executions of the second cycle in (e).

16. The coating method of claim 1, wherein a supply flow rate of the third process gas in (c) is changed according to the number of previous executions of the second cycle in (e).

17. A processing apparatus comprising:
a process vessel;
a gas supplier configured to supply a first process gas, a second process gas different from the first process gas and a third process gas different from each of the first process gas and the second process gas to the process vessel; and
a controller configured to be capable of controlling the gas supplier so as to perform:
(a) supplying a first process gas to a process vessel;
(b) supplying a second process gas different from the first process gas to the process vessel;
(c) supplying a third process gas different from each of the first process gas and the second process gas to the process vessel;
(d) performing a first cycle X times, the first cycle comprising performing (a) and (b);
(e) performing a second cycle Y times, the second cycle comprising performing (d) and (c); and
(f) changing X in a next execution of the second cycle according to the number of previous executions of the second cycle in (e).

18. A non-transitory computer-readable recording medium storing a program that causes a substrate processing apparatus, by a computer, to perform the method of claim 1.

19. A substrate processing method comprising:
(a) supplying a first process gas to a process vessel;
(b) supplying a second process gas different from the first process gas to the process vessel;
(c) supplying a third process gas different from each of the first process gas and the second process gas to the process vessel;
(d) performing a first cycle X times, the first cycle comprising performing (a) and (b);
(e) performing a second cycle Y times, the second cycle comprising performing (d) and (c);
(f) changing X in a next execution of the second cycle according to the number of previous executions of the second cycle in (e); and
(g) loading a substrate into the process vessel and processing the substrate after (e).

20. A method of manufacturing a semiconductor device comprising the method of claim 19.
